(19) United States
(12) Patent Application Publication
(10) Pub. No.: US 2005/0133249 A1
(43) Pub. Date: Jun. 23, 2005

(54) Printed wiring board and semiconductor device

(75) Inventor: Nobuaki Fujii, Shimonoseki-shi (JP)

Correspondence Address: THE WEBB LAW FIRM, P.C., 700 KOPPERS BUILDING, 436 SEVENTH AVENUE, PITTSBURGH, PA, 15219, US

(73) Assignee: MITSUI MINING & SMELTING CO., LTD.

(21) Appl. No.: 11/013,611

(22) Filed: Dec. 16, 2004

(30) Foreign Application Priority Data
Dec. 19, 2003 (JP) 2003-423766

(51) Int. Cl. H05K 1/03

(52) U.S. Cl. 174/250; 174/256

(57) ABSTRACT

A printed wiring board has a large number of wirings formed substantially parallel to one another, a dummy pattern is formed along the wirings and a solder resist layer is formed by coating the wirings and the dummy pattern with a solder resist. The coating thickness of said solder resist gradually decreases toward the edge, wherein the dummy pattern has a solder resist coating thickness control area. A semiconductor device includes the above-mentioned printed wiring board with an electronic part mounted thereon. Accordingly, a slope uniformly extending over the whole width of the solder resist layer is formed at the edge portion of the solder resist layer to improve electrical connectivity.

### FIELD OF THE INVENTION

The present invention relates to a printed wiring board having a solder resist layer in which the coating thickness of a solder resist is gradually decreased toward the edge to form a slope, and a semiconductor device. More particularly, the invention relates to a printed wiring board having a solder resist layer whose edge portion is in a shape of a slope and having a dummy pattern in a specific shape.

### BACKGROUND OF THE INVENTION

In order to mount electronic parts, a carrier having a wiring pattern on a surface of an insulating substrate is employed. Such a carrier is formed by a process comprising forming a photosensitive resin layer on a surface of a laminate consisting of an insulating substrate and a conductive metal, exposing and developing the photosensitive resin layer to form a desired pattern, selectively etching the conductive metal using the thus formed pattern as a masking material to form a wiring pattern made of the conductive metal and then coating the wiring pattern with a solder resist in such a manner that a terminal area of the wiring pattern is exposed. On an inner lead of the carrier thus formed, an IC chip or the like is mounted to prepare a semiconductor device, and a terminal of the outer lead is electrically connected to an electrode (e.g., bump electrode) of a substrate, such as a substrate of a display device or a circuit substrate of a computer, to fabricate electronic equipment.

In the mounting of the semiconductor device on such a substrate, if the thickness of the solder resist layer of the carrier is too large, the edge of the substrate and the solder resist layer come into contact with each other, so that mounting of the semiconductor device on the substrate cannot be surely effected in some cases. Therefore, in order to prevent contact of the edge of the solder resist layer with the edge of the substrate, the solder resist layer is formed so as to have a slope where the coating thickness of the solder resist layer in the edge portion is gradually decreased toward the edge.

Such a solder resist layer as mentioned above is formed by the use of screen printing technique. That is to say, a screen having been masked except an area corresponding to the area of the insulating substrate to be coated with the solder resist is superimposed on the surface of the insulating substrate having a wiring pattern, and a solder resist ink is fed to the surface of the screen. Then, a squeegee is moved on the screen to allow the solder resist ink to selectively pass through the unmasked area of the screen and thereby coat the prescribed area on the insulating substrate with the solder resist ink. Thereafter, the solder resist ink is cured to form a solder resist layer. The solder resist layer having a slope edge portion where the coating thickness is decreased toward the edge can be formed by, for example, gradually making opening sizes of an edge portion of a gauze of a screen smaller toward the edge, said portion being corresponding to an edge portion of the area to be coated with the solder resist ink, and thereby gradually decreasing the amount of the solder resist ink that passes through the gauze. By forming a solder resist layer of such a shape that the thickness is decreased toward the edge, contact of the solder resist layer with an edge of a substrate for mounting a semiconductor device can be prevented, and the semiconductor device can be favorably mounted on the substrate.

By the way, since formation of the solder resist layer in the printed wiring board, mounting of the semiconductor device on the substrate, etc. are carried out by means of automatic systems, it is necessary to perform positioning of the printed wiring board, and for the positioning, a dummy pattern is occasionally formed on the surface of the insulating substrate where the wiring pattern is not formed. Further, if the insulating substrate is a flexible film such as a polyimide film and if a wiring pattern is formed by selectively etching a conductive metal, a printed wiring board resulting from removal of the conductive metal sometimes suffers warpage deformation, and for preventing occurrence of the warpage deformation, a dummy pattern is occasionally formed.

As shown in, for example, FIG. 4 and FIG. 5, a wiring pattern 115 and a dummy pattern 111 are each a conductive pattern which is made of a conductive metal such as copper and is formed on a surface of an insulating plate 120, and the dummy pattern 111 is a solid pattern made of a conductive metal in many cases, as shown in FIG. 4. As shown in FIG. 4, further, the dummy pattern is frequently provided with an alignment mark for positioning the wiring board, such as a depression 126.

As shown in FIG. 5, when the edge portion of the solder resist layer 112 overlaps the solid dummy pattern 111, the coating thickness of the edge portion of the solder resist layer 112 on the dummy pattern 111 becomes larger than the thickness of the slope formed at the edge portion of the solder resist layer 112 on the wiring pattern 115, and a large thickness portion 110 that is larger in the thickness than the original slope portion formed on the wiring pattern 115 is formed. That is to say, there is no means of escape for the solder resist ink between the surface of the solid dummy pattern and the screen for solder resist ink coating, and therefore, if a solder resist layer 112 is formed on the solid dummy pattern 111, its edge portion becomes thicker than the slope formed on the wiring pattern 115.

If the edge portion of the solder resist layer 112 on the dummy pattern 111 becomes thicker as above, the large thickness portion 110 of the solder resist layer on the dummy pattern 111 comes into contact with, for example, an edge of a substrate electrode of a liquid crystal panel as previously described, and electrical connection to the substrate cannot be surely made in some cases.

In Japanese Patent Laid-Open Publication No. 195908/2000, it is disclosed that a slit is formed in an insulating film and by means of the slit the coating thickness of the solder resist layer is controlled. In this publication, however, there is no description about a solder resist layer in a specific shape wherein the coating thickness is decreased toward the edge of the layer to form a slope.

In Japanese Patent Laid-Open Publication No. 233547/1999, it is disclosed that when a solder resist layer of small thickness is formed in the wire bonding area and a solder resist layer of large thickness is formed in the ball pad conductive material area, a photosensitive component is added to the solder resist layer to simultaneously photo-cure both of the solder resist layer of small thickness and the solder resist layer of large thickness that is obtained by recoating. In this publication, however, there is no description about formation of a solder resist layer in a shape of a slope toward the edge.

### OBJECT OF THE INVENTION

It is an object of the present invention to provide a printed wiring board having a solder resist layer whose coating thickness is decreased toward the edge to form a slope and having a wiring pattern and a dummy pattern which are formed at the slope portion of the solder resist layer, wherein the slope uniformly extends over the whole width of the edge portion of the solder resist layer.

### SUMMARY OF THE INVENTION

The printed wiring board of the present invention is a printed wiring board having a large number of wirings formed in almost parallel to one another, a dummy pattern formed along the wirings and a solder resist layer formed by coating the wirings and the dummy pattern with a solder resist, the coating thickness of said solder resist being gradually decreased toward the edge, wherein:
the dummy pattern has a solder resist coating thickness control area.

The semiconductor device of the present invention comprises the above-mentioned printed wiring board and an electronic part mounted on the printed wiring board.

### BRIEF DESCRIPTION OF THE DRAWINGS

FIG. 1 is a sectional view showing an example of a section of a printed wiring board of the present invention.

FIG. 2 is a plan view showing an example of a printed wiring board of the present invention.

FIG. 3 is a plan view showing another example of a printed wiring board of the present invention.

FIG. 4 is a plan view showing a conventional printed wiring board having a dummy pattern.

FIG. 5 is a sectional view taken on line A-A of FIG. 4.

11: insulating substrate

13: dummy wiring

14: concavity

15: wiring pattern

17: coating thickness control area (dummy pattern)

19: solder resist layer

21: edge

22: cutout

23: slope

25: edge of depression for alignment

26: depression for alignment

27: outer peripheral metal edge

110: large thickness portion

111: solid dummy pattern

112: solder resist layer

115: wiring pattern

120: insulating substrate

126: depression for alignment

### DETAILED DESCRIPTION OF THE INVENTION

The printed wiring board and the semiconductor device of the invention are described in detail hereinafter.

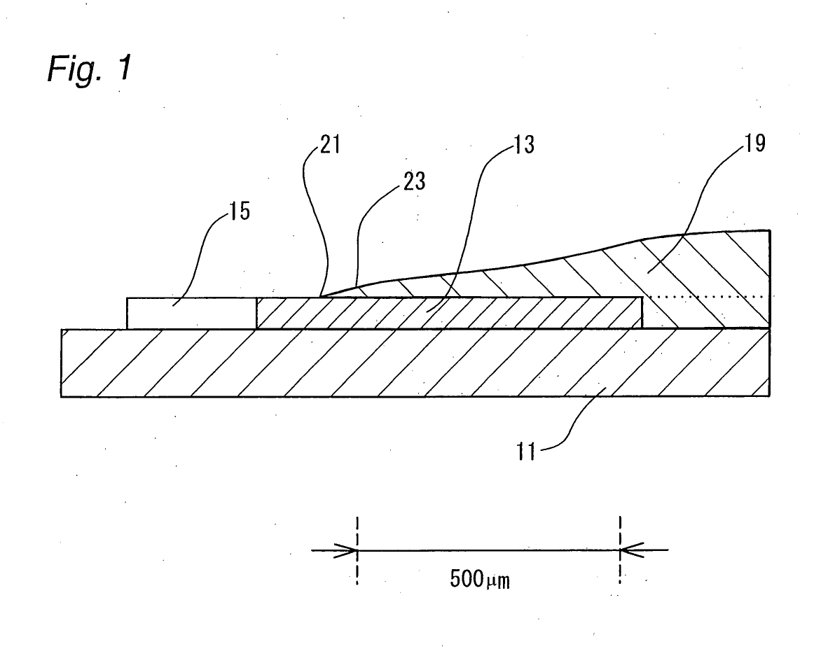

As shown in FIG. 1, the printed wiring board of the invention has an insulating substrate 11, a wiring pattern 15 formed on at least one surface of the insulating substrate 11 and a solder resist layer 19 formed in such a manner that a terminal area of the wiring pattern is exposed, and the edge portion of the solder resist layer 19 forms a slope 23 where the coating thickness is gradually decreased toward an edge 21.

In the printed wiring board of the invention, the insulating substrate 11 may be a flexible substrate or a rigid substrate.

Examples of the insulating substrates 11 in the printed wiring board of the invention include polyimide, polyamide, polyester, polyphenylene sulfide, polyether imide and liquid crystal polymer. When a flexible substrate is used as the insulating substrate 11, a polyimide film is preferable. When the polyimide film is used as the flexible substrate, the thickness of the polyimide film is not specifically restricted. However, a polyimide film having a thickness of 5 to 150 μm is preferably employed, and under the recent needs for thinning of electronic parts, a polyimide film having a thickness of 15 to 70 μm is particularly preferably employed.

On the surface of the insulating substrate 11 of the printed wiring board of the invention, a wiring pattern 15 is formed. The wiring pattern 15 can be formed by a process comprising forming a conductive metal layer on the surface of the insulating substrate 11, then coating the surface of the conductive metal layer with a photoresist to form a photoresist layer, exposing and developing the photoresist layer to give a desired pattern and selectively etching the conductive metal using the pattern of the photoresist as a masking material.

The conductive metal employable herein is, for example, copper or aluminum. The conductive metal layer can be formed also by bonding, for example, a copper foil to the insulating substrate, or can be formed also by depositing a conductive metal on the surface of the insulating substrate. The conductive metal layer may be a layer of one metal, or may be a laminate of plural metals. In case of, for example, deposition of a conductive metal, it is possible that a metal such as chromium or nickel is sputtered on the surface of the insulating substrate and then a conductive metal such as copper is electrodeposited thereon. The thickness of the conductive metal layer is in the range of usually 5 to 70 μm, preferably 8 to 35 μm.

In the present invention, a solder resist layer having a given thickness ranging from usually 1 to 75 μm, preferably. 10 to 55 μm, is formed on the area of the wiring pattern 15 to be surely protected, similarly to a conventional solder resist layer, and in the vicinity of a terminal area, a slope 23 of the solder resist layer is formed. That is to say, in the vicinity of the terminal formed at the edge of the wiring pattern 15, the coating thickness of the solder resist is continuously or stepwise decreased in the direction of the terminal to form a slope of the solder resist layer.

In the present invention, the thickness of the cured solder resist is continuously or stepwise decreased in the area having a width of usually 100 to 2000 μm, preferably 250 to 2000 μm, more preferably 300 to 2000 μm, particularly preferably 400 to 1000 μm, from the edge of the solder resist layer.

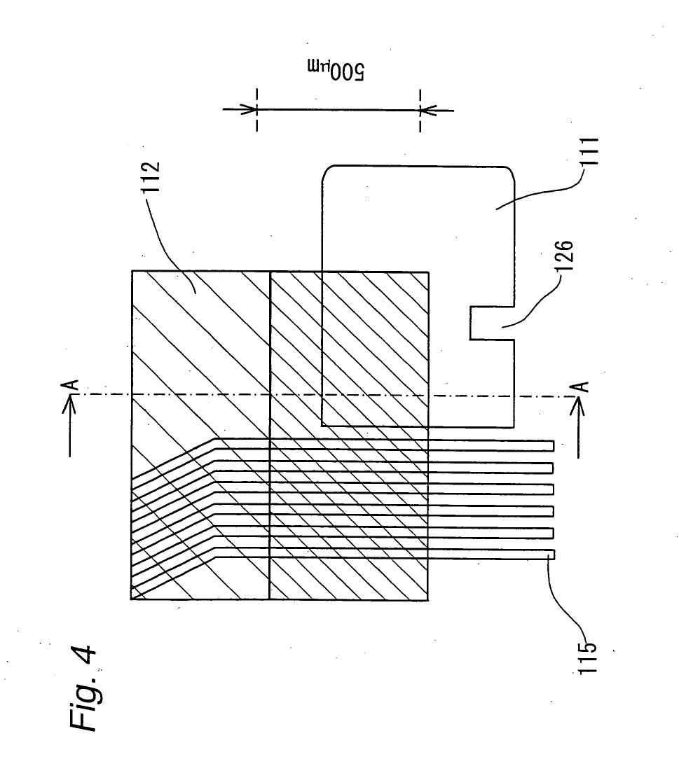

The dummy pattern is an electrically non-connected pattern that is formed along the outermost wiring of the wiring pattern and is usually an independent flat solid pattern (Herein “solid pattern” indicates a pattern having a wide area (e.g. plane-like area) of a conductive metal which has not been etched), as designated by numeral 111 in FIG. 4. The dummy pattern is sometimes formed as a mark for alignment of the resulting printed wiring board, which is used when an electronic part is mounted on the printed wiring board. When the insulating substrate is an insulating film, the area where the wiring pattern made of a conductive metal is formed and the area where no wiring pattern is formed are different from each other in the stress, and the resulting film carrier is liable to suffer warpage deformation. Therefore, if a dummy pattern is formed on the area where no wiring-pattern is formed, the whole of the printed wiring board is covered with a pattern. As a result, unevenness of the internal stress in the printed wiring board is reduced, and occurrence of warpage deformation of the printed wiring board can be effectively prevented.

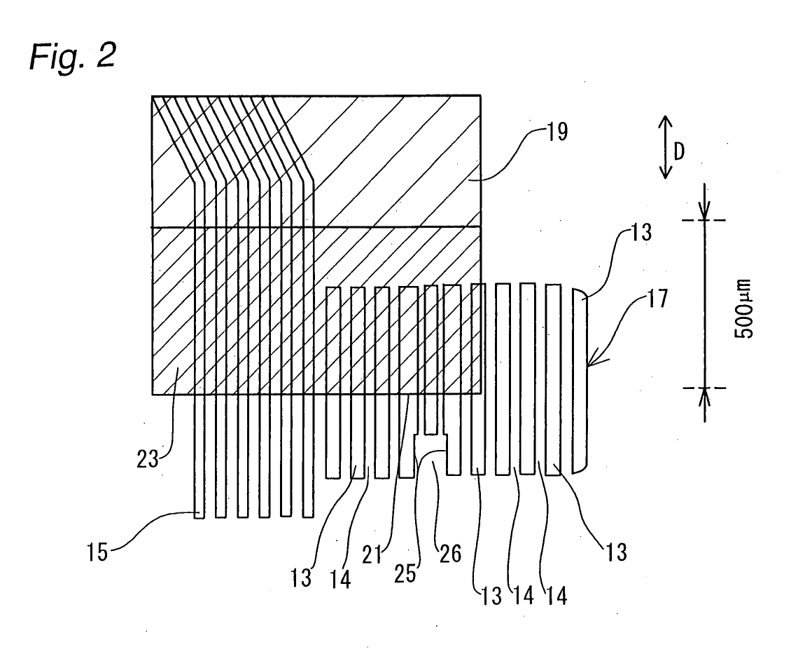

In FIG. 2, the dummy pattern is designated by numeral 17.

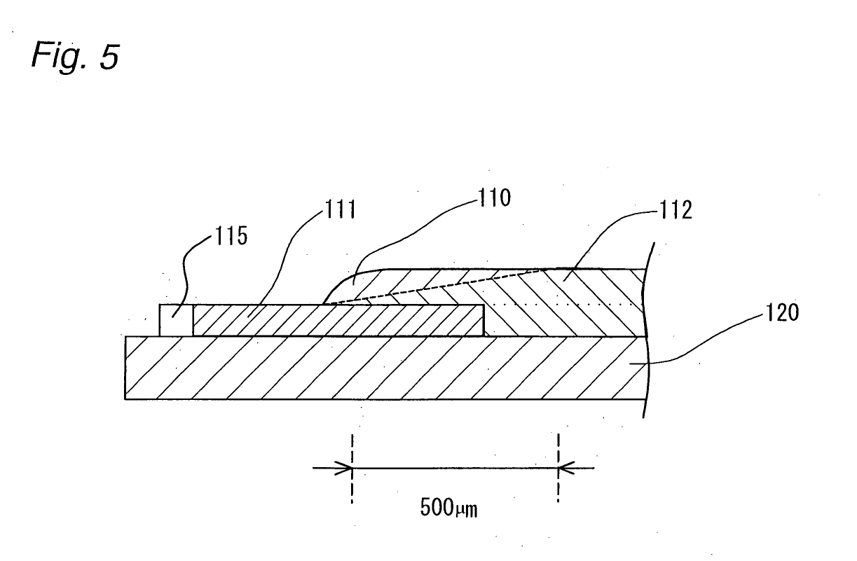

The solid dummy pattern mentioned above is a solid pattern made of a conductive metal. Therefore, if the slope at the edge portion of the solder resist layer lies on the solid dummy pattern, the solder resist ink is fed onto the solid dummy pattern excessively as much as about the thickness of the conductive metal for forming the solid dummy pattern. This excess amount of the solder resist ink fed onto the solid dummy pattern stays, below the lower surface of the screen used for solder resist coating because the screen has flexibility, and as a result, such a large thickness portion 110 as shown in FIG. 5 is formed.

In the printed wiring board of the invention, a dummy pattern 17 is formed in such a manner that the dummy pattern consists of fine dummy wirings 13 and concavities 14 (in other words, “spaces” or “gaps” to keep the excess solder resist ink) formed between the dummy wirings 13, as shown in FIG. 2. That is to say, the dummy pattern 17 is composed of a large number of fine wires formed in almost parallel to a wiring pattern 15 consisting of a large number of wirings which are almost parallel to one another and concavities 14 which keep the neighboring fine wires apart from each other. Between the dummy wiring (fine wire) 13 and its neighboring dummy wiring (fine wire) 13 thus formed, there is no pattern. Therefore, between a large number of the dummy wirings 13, the insulating substrate is exposed to form the concavities 14. That is to say, the bottoms of the concavities 14 are parts of the insulating substrate, and the sidewalls thereof are formed from the dummy wirings 13.

The dummy wirings 13 are preferably formed in almost parallel to a large number of wirings of the wiring pattern 15. In the formation of the solder resist layer 19, a squeegee is moved on the screen in the direction of an arrow D to apply a solder resist ink that is a high-viscosity liquid containing an organic solvent, so that it is preferable to form the dummy wirings 13 in almost parallel to the moving direction of the squeegee, namely, in almost parallel to a large number of wirings of the wiring pattern 15.

By dividing the dummy pattern into a large number of dummy wirings 13 as described above, each of the concavities 14 formed between the dummy wirings 13 becomes a solder resist coating thickness control area for keeping the excess solder resist ink. In such a dummy pattern as shown in FIG. 2, which has a large number of dummy wirings 13 formed in almost parallel to a large number of wirings of the wiring pattern 15, the coating thickness control area 17 is formed from each concavity 14 formed between the dummy wirings 13.

By forming the coating thickness control area 17, a part of the solder resist ink fed onto the dummy pattern flows into the concavities 14 formed between the dummy wirings 13, and therefore, formation of such a large thickness portion 110 as shown in FIG. 5 ascribed to the excess solder resist ink fed onto the dummy pattern is prevented. Consequently, the solder resist layer 19 is uniformly formed even on the dummy pattern similarly to that on the wiring pattern, and a slope 23 uniformly extending over the whole width of the edge portion of the solder resist layer 19 can be formed.

Outside the outermost wiring of the wiring pattern 15 consisting of a large number of wirings, an outermost dummy wiring of the dummy wirings 13 is formed in an almost equal interval to that in the neighboring wiring pattern 15, and therefore, over-etching of the outermost wiring of the wiring pattern 15 does not take place.

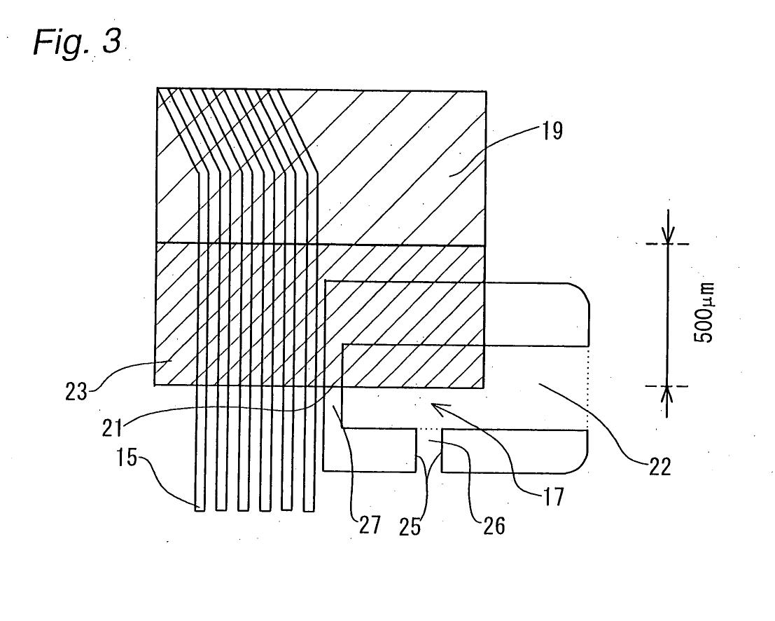

In the printed wiring board of the invention, the dummy pattern can be formed also by removing at least a part of an outer periphery of the dummy pattern and the conductive metal present inside with leaving at least a part the outer periphery of the dummy pattern so that the original shape of the dummy pattern is recognizable, as shown in FIG. 3. That is to say, in FIG. 3, the dummy pattern is a pattern made of a conductive metal, which is indicated by a broken line and a solid line, and in the solder resist layer 19, a slope 23 where the thickness is gradually decreased toward an edge 21 of the layer is formed. In the embodiment shown in FIG. 3, the conductive metal is greatly removed from the right-hand side of the dummy pattern 17, namely, the side where the wiring pattern 15 consisting of a large number of wirings is not formed, to form a cutout 22. That is to say, an outer peripheral metal edge 27 is formed so as to make a contour of the original shape of the dummy pattern, and the conductive metal surrounded by the outer peripheral metal edge 27 is removed to form the cutout 22 (in other words, “a space” or “a gap” to keep the excess solder resist ink). The cutout 22 is formed in such a manner that the slope 23 and the edge 21 of the solder resist layer 19 are located inside the cutout 22. By forming the cutout 22 in the above manner and forming the solder resist layer so that a part or the whole of the slope 23 and the edge 21 of the solder resist layer 19 should be located inside the cutout 22, the cutout 22 becomes a coating thickness control area 17 which is depressed from the outer peripheral metal edge 27 as much as the thickness of the conductive metal, and for example, an excess solder resist ink produced when the solder resist ink is applied onto the outer peripheral metal edge 27 on the side of the wiring pattern 15 is kept in the cutout 22. Consequently, the solder resist layer 19 is formed uniformly even on the dummy pattern similarly to that on the wiring pattern 15, and a slope 23 uniformly extending over the whole width of the edge portion of the solder resist layer 19 can be formed.

In the dummy pattern shown in FIG. 2 and FIG. 3, an edge 25 for alignment with a substrate such as a substrate of a display device is formed, and in the alignment operation, the position of the edge of the conductive metal having been etched and the shape surrounded by the edge are usually used. For example, in FIG. 2, parts of dummy wirings are cut out to expose the insulating substrate in a prescribed shape, and also in FIG. 3, a cutout is likewise formed, whereby alignment can be carried out similarly to the case using a conventional solid dummy pattern.

By virtue of the dummy pattern formed as above, the degree of warpage deformation of the printed-wiring board becomes equivalent to that in the case where a conventional solid dummy pattern is formed.

In the production of the printed wiring board of the invention, the solder resist layer in which the coating thickness is decreased toward the edge to form a slope can be formed at one time by the use of a screen for solder resist coating. This screen comprises a frame and a gauze stretched on the frame and is produced in such a manner that the amount of a solder resist coating solution that passes through the gauze should be decreased stepwise or continuously toward a masking zone. The solder resist layer in which the coating thickness is decreased toward the edge to form a slope can be formed also by performing application of a solder resist plural times and thereby gradually decreasing or gradually increasing the coated area.

The solder resist ink thus applied is then cured by, for example, thermal curing or photo curing, to form a solder resist layer.

After the solder resist layer is formed as above, the wiring pattern having been coated with no solder resist layer (lead portion) is usually subjected to plating.

The plating adoptable herein is, for example, tin plating, gold plating, nickel-gold plating, solder plating or lead-free solder plating. The plating treatment may be carried out in the following manner. Prior to the solder resist coating, a thin plated layer is formed on the wiring pattern and the dummy pattern, then on this thin plated layer, a solder resist layer is formed, and the connecting terminal exposed from the solder resist layer is further subjected to plating. The thickness of the plated layer can be appropriately determined according to the type of the plating, and the total of the plated layers is determined in the range of usually 0.2 to 0.8 μm, preferably 0.3 to 0.6 μm.

On the terminal area (inner lead portion) thus plated, an electronic part such as an IC chip is mounted, and then resin sealing is carried out, whereby a semiconductor device can be obtained.

The printed wiring board of the invention is suitable as a printed wiring board provided with a wiring pattern having an outer lead width of 15 μm to 3 mm, preferably 20 to 150 μm, an outer lead pitch width of 30 μm to 5 mm, preferably 40 to 300 μm, an inner lead width of not more than 65 μm, preferably 5 to 35 μm and an inner lead pitch width of not more than 100 μm, preferably 20 to 70 μm. Examples of such printed wiring boards include printed wiring board (PWB), TAB (tape automated bonding) tape, COF (chip on film), CSP (chip size package), BGA (ball grid array), μ-BGA (μ-ball grid array) and FPC (flexible printed circuit). The printed wiring board of the invention may be a printed wiring board having an electronic part mounted thereon, namely, a semiconductor device, as previously described.

The printed wiring board and the semiconductor device of the invention are described above using two types of dummy patterns, but they can be variously modified within limits not detrimental to the object of the present invention.

### EFFECT OF THE INVENTION

In the printed wiring board of the invention, a coating thickness control area to control the coating thickness of the solder resist is formed in the dummy pattern, and therefore, a solder resist layer in which the coating thickness is gradually decreased toward the edge of the layer to form a slope can be formed uniformly even on the dummy pattern similarly to that on the wiring pattern.

Further, even when a solder resist coating thickness control area is formed in the dummy pattern as described above, various functions inherent in the dummy pattern, such as an alignment function and a function of preventing deformation of the printed wiring board due to etching, are not impaired.

### EXAMPLES

The printed wiring board and the semiconductor device of the present invention are further described with reference to the following examples, but it should be construed that the invention is in no way limited to those examples.

### Example 1

A laminate consisting of a polyimide film (available from Ube industries, Ltd., Upilex S) having a thickness of 75 μm and an electrodeposited copper foil having a thickness of 18 μm was prepared.

The surface of the electrodeposited copper foil of the laminate was coated with a photoresist, and the photoresist was exposed and developed to form a lead pattern and a fine wire pattern that was almost parallel to the lead pattern, as shown in FIG. 2. Then, using the thus formed patterns as masking materials, the copper foil was selectively etched with an etching solution to form a prescribed wiring pattern. In the wiring pattern thus formed, such a dummy pattern constituted of a large number of fine wires almost parallel to the outer leads as shown in FIG. 2 was formed by the side of the outer leads. The pitch of the outer leads was 80 μm (lead width: 40 μm, space: 40 μm), and the space between the outermost lead of the outer leads and the dummy pattern was 40 μm. The width of the fine wire to form the dummy pattern was 40 μm that was equal to the width of the outer lead, and the space between the fine wires was 40 μm. In the dummy pattern, a depression 26 for alignment of the film carrier was formed.

Separately, a screen for solder resist coating was prepared.

This screen was obtained by stretching, on an aluminum frame, a screen constituted of stainless steel fine wires having a wire diameter of 60 μm and having a mesh size of 150 mesh.

The screen was coated with a photosensitive resin, and the resin was exposed and developed to give a prescribed pattern and thereby form a coating solution passing zone for allowing a solder resist coating solution to pass through.

Then, the edge portion of the coating solution passing zone on the side where a lead was to be formed was masked in a width of 170 μm, and the coating solution passing zone was coated with a resin. After the resin was cured, the masking material was removed, and the screen was immersed in an electroless nickel plating solution to form a nickel plated layer around each stainless steel fine wire having a wire diameter of 60 μm present in the above-mentioned 170 μm-width area.

After the stainless steel fine wires present in the 170 μm-width area were subjected to nickel plating of the first time as above, the screen was taken out of the plating solution, and the resin coating was removed from the coating solution passing zone.

Then, the edge portion of the coating solution passing zone of the screen on the side where a lead was to be formed was masked in a width of 340 μm (170 μm×2=340 μm), and the coating solution passing zone was coated with a resin. After the resin was cured, the masking material was removed, and the screen was immersed in an electroless nickel plating solution to form a nickel plated layer around each stainless steel fine wire present in the above-mentioned area of a width of 340 μm. As a result, the screen fine wires present in the 170 μm-width area from the edge of the coating solution passing zone had been nickel plated two times, and the screen fine wires present in the 170 μm-width area located inside the above 170 μm-width area had been nickel plated one time.

After the stainless steel fine wires present in the 340 μm-width area were subjected to nickel plating as above, the screen was taken out of the plating solution, and the resin coating was removed from the coating solution passing zone.

Then, the edge portion of the coating solution passing zone of the screen on the side where a lead was to be formed was masked in a width of about 500 μm (170 μm×2=510 μm), and the coating solution passing zone was coated with a resin. After the resin was cured, the masking material was removed, and the screen was immersed in an electroless nickel plating solution to form a nickel plated layer around each stainless steel fine wire present in the above-mentioned area of a width of about 500 μm. As a result, the screen fine wires present in the 170 μm-width area from the edge of the coating solution pressing zone had been nickel plated three times, the screen fine wires present in the 170 μm-width area located inside the above 170 μm-width area had been nickel plated two times, and the screen fine wires present in the 170 μm-width area located further inside the above 170 μm-width area had been nickel plated one time.

After the stainless steel fine wires present in the area of a width of about 500 μm were subjected to nickel plating as above, the screen was taken out of the plating solution, and the resin coating was removed from the coating solution passing zone.

By stepwise carrying out nickel plating three times as described above, the stainless steel fine wires present in the area of a width of 170 μm from the edge of the cured photosensitive resin for forming the coating solution passing zone had been nickel plated three times, and the opening size in this area was 50 μm. As the center of the coating solution passing zone was approached, the opening sizes became larger stepwise, and the opening size in the area having been subjected to no plating under the protection of the resin coating was 109 μm.

To the surface of the screen prepared as above, a solder resist ink was fed, then the solder resist ink was applied onto the wiring pattern by the use of a squeegee, and the solder resist ink was cured by heating to form a solder resist layer.

In the region of 500 μm from the edge of the solder resist layer thus formed, the thickness of the solder resist was gradually decreased toward the edge to form a slope.

When the edge portion of the solder resist layer was observed, the solder resist layer had a slope uniformly extending from the wiring pattern to the dummy pattern, and the aforesaid large thickness portion was not observed on the dummy pattern.

When the wiring pattern of the film carrier obtained above was observed, there was no difference in the width between the outermost wiring and other wirings in the wiring pattern 15 constituted of a large number of wirings which were almost parallel to one another.

On the film carrier, a semiconductor chip was mounted to prepare a semiconductor device. Then, alignment of the film carrier with a glass substrate of a liquid crystal panel was carried out using an edge 25 of the depression 26 of the dummy pattern present on the side of the output side outer leads, and as a result, alignment could be normally made. Further, electrical connection by means of ACF could be also made without problem, and no connection failure took place.

### Example 2

A film carrier was prepared in the same manner as in Example 1, except that the shape of the dummy pattern was changed as shown in FIG. 3. That is to say, at the position 40 μm apart from the edge of the wiring pattern 15 constituted of plural wirings formed in almost parallel to one another, a dummy pattern was formed so that an outer peripheral metal edge 27 became parallel to the plural wirings of the wiring pattern 15. This dummy pattern had a cutout 22 formed in such a manner that a center portion of a solid dummy pattern was removed from the side which did not face the wiring pattern 15. In the dummy pattern, a depression 26 for alignment was formed. The bottom of the depression 26 was connected with the cutout 22, and the outer peripheral metal edge 27 was discontinuous at the position of the depression 26.

When the edge portion of the above-prepared solder resist layer having a slope length of 500 μm was observed, the solder resist layer had a slope uniformly extending from the wiring pattern to the dummy pattern, and the aforesaid large thickness portion was not observed on the dummy pattern.

On the film carrier, a semiconductor chip was mounted to prepare a semiconductor device. Then, alignment of the film carrier with a glass substrate of a liquid crystal panel was carried out using an edge 25 of the depression 26 of the dummy pattern present on the side of the output side outer leads, and as a result, alignment could be normally made. Further, electrical connection by means of ACF could be also made without problem, and no connection failure took place.

Further, warpage deformation of the film carrier attributable to the formation of the dummy pattern having such a shape as mentioned above was on a level with that of a conventional product.

### Comparative Example 1

A film-carrier was prepared in the same manner as in Example 1, except that such a solid dummy pattern as shown in FIG. 4 was formed.

Although the solder resist layer was formed in the film carrier in the same manner as in Example 1, the solder resist layer did not uniformly extend from the wiring pattern to the dummy pattern, and the aforesaid large thickness portion was observed on the dummy pattern. Further, in the ACF connections between the liquid crystal panel and the outer leads of the film carrier, some electrical connection failures were observed.

1. A printed wiring board having a large number of wirings formed substantially parallel to one another, a dummy pattern formed along the wirings and a solder resist layer formed by coating the wirings and the dummy pattern with a solder resist, the coating thickness of said solder resist being gradually decreased toward the edge, wherein:
the dummy pattern has a solder resist coating thickness control area.

2. The printed wiring board as claimed in claim 1, wherein the solder resist coating thickness control area is formed by dividing the dummy pattern into dummy fine wires and dummy spaces between the dummy fine wires, said dummy fine wires being substantially parallel to the large number of the wirings formed substantially parallel to one another.

3. The printed wiring board as claimed in claim 1, wherein the solder resist coating thickness control area is formed from a space of the dummy pattern, said space being formed by removing at least a part of an outer periphery of the dummy pattern and the interior of the dummy pattern with leaving at least a part of the outer periphery of the dummy pattern in such a manner that the original shape of the dummy pattern is recognizable.

4. The printed wiring board as claimed in claim 1, wherein the dummy pattern is any one of an alignment mark and a deformation-preventing dummy pattern.

5. A semiconductor device comprising the printed wiring board of claim 1 and an electronic part mounted on the printed wiring board.

6. A semiconductor device comprising the printed wiring board of claim 2 and an electronic part mounted on the printed wiring board.

7. A semiconductor device comprising the printed wiring board of claim 3 and an electronic part mounted on the printed wiring board.

8. A semiconductor device comprising the printed wiring board of claim 4 and an electronic part mounted on the printed wiring board.
